(19) United States
(12) Patent Application Publication
(10) Pub. No.: US 2024/0055234 A1
(43) Pub. Date: Feb. 15, 2024

(54) SUBSTRATE PROCESSING APPARATUS

(71) Applicant: PSK INC., Gyeonggi-do (KR)

(72) Inventors: Kwang Bo SIM, Gyeonggi-do (KR); Sang Yeol LEE, Gyeonggi-do (KR); Ji Hoon YOON, Gyeonggi-do (KR); Seung Ye YU, Gyeonggi-do (KR)

(21) Appl. No.: 18/270,804

(22) PCT Filed: Nov. 25, 2021
(86) PCT No.: PCT/KR2021/017513

§ 371 Date: Jul. 3, 2023

(30) Foreign Application Priority Data
Jan. 4, 2021 (KR) 10-2021-0000477
Oct. 27, 2021 (KR) 10-2021-0144940

(51) Int. Cl. H01J 37/32

(52) U.S. Cl. CPC H01J 37/32513; H01J 2237/2006

(57) ABSTRACT

Disclosed is an apparatus for processing a substrate, the apparatus including: a housing providing a processing space therein; support unit disposed within the housing and supporting a substrate; and a plasma generating unit provided above the housing, in which the plasma supplying unit includes: a plasma chamber with a discharge space formed inside; a diffusion member provided between the plasma chamber and the housing, and diffusing plasma; a plasma source for generating plasma in the discharge space from process gas; and a sealing member provided between a lower flange of the plasma chamber and an upper flange of the diffusion member, and the sealing member includes: an inner sealing member inserted into a mounting groove formed in an upper surface of the upper flange; and an outer sealing member inserted into a space formed by combination of the upper flange and the lower flange, and positioned at a further outward side from the discharge space than the inner sealing member.

### TECHNICAL FIELD

The present invention relates to a substrate processing apparatus, and more particularly, to a substrate processing apparatus having a sealing member.

### BACKGROUND ART

Typically, a semiconductor manufacturing device utilizes an O-ring as a sealing member to maintain the vacuum inside a chamber. A typical O-ring is physically squeezed to close the gap formed between a component and a component. However, in a conventional O-ring sealing structure, the O-ring and a surrounding structure of the O-ring may expand under high heat. As a result, the tightness of the sealing structure may be weakened and outside gases may enter the chamber or process gases inside the chamber may be discharged to the outside of the chamber.

Also, depending on the nature of the process gas used inside the chamber, the sealing structure of the O-ring can be damaged. If the sealing structure is damaged, particles from the damage may enter the chamber, causing process failure and weakening the fastening force of the sealing structure.

FIG. 1 is a diagram illustrating portions of a plasma source unit and a chamber in a substrate processing apparatus using plasma. FIG. 2 is an enlarged view illustrating a connection part between the plasma source unit and the chamber. Referring to FIGS. 1 and 2, a gap may be formed between a lower end of a plasma source unit 1000 and an upper end of a chamber 2000. To seal the gap, an O-ring 3000 is installed between the plasma source unit 1000 and the chamber 2000, and the O-ring 3000 is exposed to process gas and/or heat through the fine gap formed between the plasma source unit 1000 and the chamber 2000. The fastened O-ring 3000 is etched by the process gas or thermally deformed by heat. As a result, the damaged O-ring 3000 causes process leakage and increases the maintenance time and cost of replacing the damaged O-ring 3000.

### Technical Problem

An object of the present invention is to provide a substrate processing apparatus capable of minimizing damage to a sealing member for maintaining a vacuum inside the apparatus.

Another object of the present invention is to provide a substrate processing apparatus capable of efficiently maintaining a pressure inside the apparatus.

Another object of the present invention is to provide a substrate processing apparatus capable of increasing the life of a sealing member, thereby reducing maintenance costs and time.

The problem to be solved by the present invention is not limited to the above-mentioned problems, and the problems not mentioned will be clearly understood by those skilled in the art from the present specification and the accompanying drawings.

### Technical Solution

An exemplary embodiment of the present invention provides an apparatus for processing a substrate, the apparatus including: a housing providing a processing space therein; support unit disposed within the housing and supporting a substrate; and a plasma generating unit provided above the housing, in which the plasma supplying unit includes: a plasma chamber with a discharge space formed inside; a diffusion member provided between the plasma chamber and the housing, and diffusing plasma; a plasma source for generating plasma in the discharge space from process gas; and a sealing member provided between a lower flange of the plasma chamber and an upper flange of the diffusion member, and the sealing member includes: an inner sealing member inserted into a mounting groove formed in an upper surface of the upper flange; and an outer sealing member inserted into a space formed by combination of the upper flange and the lower flange, and positioned at a further outward side from the discharge space than the inner sealing member.

According to the exemplary embodiment, the inner sealing member may include: a body portion inserted into the mounting groove; and a protrusion formed to protrude from the body portion, and the body portion may include an inner portion provided at an inner side from the discharge space and an outer portion provided at an outer side from the discharge space.

According to the exemplary embodiment, the inner portion may be provided of a material that is more corrosion resistant to plasma than a material of the outer portion.

According to the exemplary embodiment, the outer portion and/or the protrusion may be formed of a elastically deformable material to seal a gap formed by a contact of the upper flange and the lower flange.

According to the exemplary embodiment, the protrusion may extend from a lower end of the body portion, and be formed with an inclination.

According to the exemplary embodiment, the protrusion may be formed with a downward inclination toward a direction away from the discharge space.

According to the exemplary embodiment, the protrusion may extend from an upper end of the body portion and be formed with an upward inclination in a direction away from the discharge space.

According to the exemplary embodiment, a width of the protrusion may be provided to be smaller than a width of the body portion when viewed in cross-section.

According to the exemplary embodiment, a width of the protrusion may be provided to be greater than a width of the body portion when viewed in cross-section.

According to the exemplary embodiment, the upper flange may have an inclined surface at an edge to surround an edge of the lower flange, and the space may be formed by combination of the inclined surface and the edge of the lower flange.

According to the exemplary embodiment, the sealing member may be provided in a ring shape.

Another exemplary embodiment of the present invention provides an apparatus for processing a substrate, the apparatus including: a sealing member for sealing a gap between a first member and a second member, which is in contact with the first member, in which the sealing member includes: an inner sealing member inserted into a mounting groove formed in an upper surface of the second member; and an outer sealing member provided on a further outer side than the inner sealing member, and inserted into a space formed at edges of the first member and the second member, and the inner sealing member includes: a body portion inserted into a mounting groove formed in an upper surface of the first member; and a protrusion formed to protrude from the body portion.

According to the exemplary embodiment, the body portion may be formed by an inner portion provided at an inner side of the body portion and an outer portion provided at an outer side of the body portion.

According to the exemplary embodiment, the inner portion may be provided of a material that is more corrosion resistant to plasma than a material of the outer portion.

According to the exemplary embodiment, the outer portion and/or the protrusion may be formed of an elastically deformable material.

According to the exemplary embodiment, the protrusion may extend from a lower end of the body portion, and be formed with an inclination.

According to the exemplary embodiment, the protrusion may be formed with a downward inclination toward a direction away from the inner portion.

According to the exemplary embodiment, the protrusion may include: a first protrusion formed with an upward inclination toward a direction away from the inner portion; and a second protrusion formed with a downward inclination toward a direction away from the inner portion.

According to the exemplary embodiment, the protrusion may extend from an upper end of the body portion and be formed with an upward inclination toward a direction away from the inner portion.

According to the exemplary embodiment, the sealing member may be provided in a ring shape.

### Advantageous Effects

According to the exemplary embodiment of the present invention, it is possible to minimize damage to the sealing member by pressure change inside the chamber.

Further, according to the exemplary embodiment of the present invention, it is possible to minimize damage to the sealing member by plasma inside the chamber.

Further, according to the exemplary embodiment of the present invention, it is possible to prevent plasma or gas flowing inside the chamber from escaping outside the chamber.

Further, according to the exemplary embodiment of the invention, it is possible to efficiently maintain the pressure inside the apparatus.

Furthermore, according to the exemplary embodiment of the present invention, it is possible to increase the durability of the sealing member, thereby reducing the cost and time required for maintenance of the substrate processing apparatus.

The effects of the invention are not limited to those described above, and those not described will be apparent to those skilled in the art from this specification and the accompanying drawings.

### DESCRIPTION OF DRAWINGS

FIG. 1 is a diagram illustrating portions of a plasma source unit and a chamber in a substrate processing apparatus using plasma.

FIG. 2 is an enlarged view illustrating a connection part between the plasma source unit and the chamber.

FIG. 3 is a diagram schematically illustrating a substrate processing apparatus according to an exemplary embodiment of the present invention.

FIG. 4 is a diagram schematically illustrating an exemplary embodiment of a process chamber of the substrate processing apparatus of FIG. 3 that performs a plasma treatment process.

FIG. 5 is a perspective view schematically illustrating an exemplary embodiment of a sealing member and an upper flange of FIG. 4.

FIG. 6A is a cutaway perspective view of an inner sealing member of FIG. 4.

FIG. 6B is a cross-sectional view of the inner sealing member of FIG. 4.

FIGS. 7A and 7B are drawings illustrating a sealing process by the sealing member of FIG. 4.

FIG. 8 is a diagram schematically illustrating another exemplary embodiment of the sealing member of FIG. 4.

FIGS. 9A and 9B are drawings illustrating a sealing process by the sealing member of FIG. 8.

FIGS. 10 through 14 are drawings schematically illustrating other exemplary embodiments of the sealing member of FIG. 4.

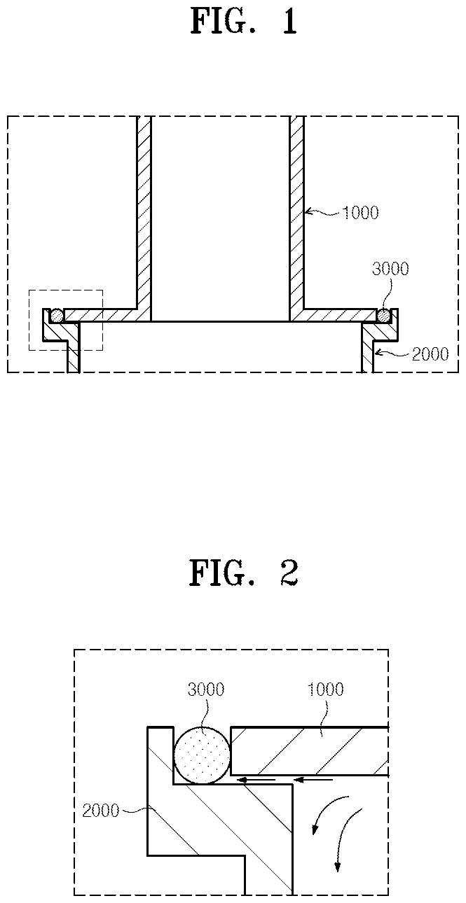

### BEST MODE

Hereinafter, exemplary embodiments of the present invention will be described in more detail with reference to the accompanying drawings. Exemplary embodiments of the present invention may be modified in many ways and should not be construed as limiting the scope of the invention to the exemplary embodiments described below. The present exemplary embodiments are provided to more fully illustrate the invention to one of average skill in the art. Therefore, the geometry of the components in the drawing is exaggerated to emphasize a clearer explanation.

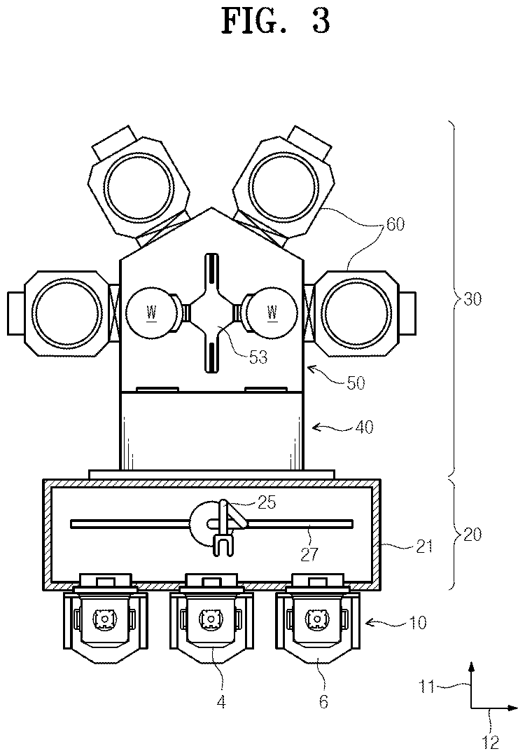

Exemplary embodiments of the present invention will now be described in detail with reference to FIGS. 3 to 14.

FIG. 3 is a diagram schematically illustrating a substrate processing apparatus according to an exemplary embodiment of the present invention. Referring to FIG. 3, a substrate processing apparatus 1 includes an equipment front end module (EFEM) 20 and a processing module 30. The equipment front end module 20 and the processing module 30 are disposed in one direction. Hereinafter, the direction in which the equipment front end module 20 and the processing module 30 are arranged is defined as a first direction 11. Further, a direction perpendicular to the first direction 11 is defined as a second direction 12 when viewed from above, and a direction perpendicular to both the first direction 11 and the second direction 12 is defined as a third direction 13.

The equipment front end module 20 includes a load port 10 and a transfer frame 21. The load port 10 is disposed at the front of the equipment front end module 20 in the first direction 11. The load port 10 includes a plurality of support parts 6. The support parts 6 are disposed in series in the second direction 12, and a carrier C (for example, a cassette, and an FOUP) in which a substrate W that is to be provided for a process and a processing completed substrate W is accommodated is seated on each support part 6. In the carrier C, the substrate W to be provided to the process and the substrate W that has been completely processed are accommodated. The transfer frame 21 is disposed between the load port 10 and the processing module 30. The transfer frame 21 includes a first transfer robot 25 disposed therein and transferring the substrate W between the load port 10 and the processing module 30. The first transfer robot 25 moves along a transfer rail 27 provided in the second direction 12 to transfer the substrate W between the carrier C and the processing module 30.

The processing module 30 includes a load lock chamber 40, a transfer chamber 50, and a process chamber 60.

The load lock chamber 40 is disposed adjacent to the transfer frame 21. In one example, the load lock chamber 40 may be disposed between the transfer chamber 50 and the equipment front end module 20. The load lock chamber 40 provides a waiting space for substrates W to be provided to the process before the substrates W are transferred to the process chamber 60, or for substrates W that have completely processed before the substrates W are transferred to the equipment front end module 20.

The transfer chamber 50 is disposed adjacent to the load lock chamber 40. The transfer chamber 50 has a polygonal body when viewed from the top. In one example, the transfer chamber 50 may have a pentagonal body when viewed from the top. On the outer side of the body, the load lock chamber 40 and the plurality of process chambers 60 are disposed along the circumference of the body. On each sidewall of the body, a passageway (not illustrated) is formed for the substrate W to enter and exit, and the passageway connects the transfer chamber 50 to the load lock chamber 40 or the process chambers 60. Each passageway is provided with a door (not illustrated) for opening and closing the passageway to seal the interior.

In the interior space of the transfer chamber 50, a second transfer robot 53 is arranged to transfer the substrate W between the load lock chamber 40 and the process chambers 60. The second transfer robot 53 transfers the unprocessed substrate W waiting in the load lock chamber 40 to the process chamber 60, or transfers the completely processed substrate W to the load lock chamber 40. The substrate W is then transferred between the process chambers 60 to sequentially provide the substrate W to the plurality of process chambers 60. For example, as illustrated in FIG. 3, when the transfer chamber 50 has a pentagonal body, the load lock chamber 40 is arranged on each of the sidewalls adjacent to the equipment front end module 20, and the process chambers 60 are consecutively arranged on the remaining sidewalls. The shape of the transfer chamber 50 is not limited thereto, but may be provided in various variations depending on the required process module.

The process chamber 60 is disposed along the circumference of the transfer chamber 50. A plurality of process chambers 60 may be provided. Within each process chamber 60, a process treatment is performed on the substrate W. The process chamber 60 receives the substrate W from the second transfer robot 53, performs the process treatment, and provides the substrate W after the process treatment is completed to the second transfer robot 53. The process treatment performed in each process chamber 60 may differ from each other.

The process treatments performed in each process chamber 60 may be different from each other. The process performed by the process chamber 60 may be one process in the process of producing a semiconductor device or a display panel by using the substrate W. The substrate W processed by the substrate processing apparatus 1 is an inclusive concept that includes all substrates used in the manufacture of semiconductor devices, Flat Panel Displays (FPDs), and other articles with circuit patterns formed on thin films. Examples of such substrates W include silicon wafers, glass substrates, or organic substrates.

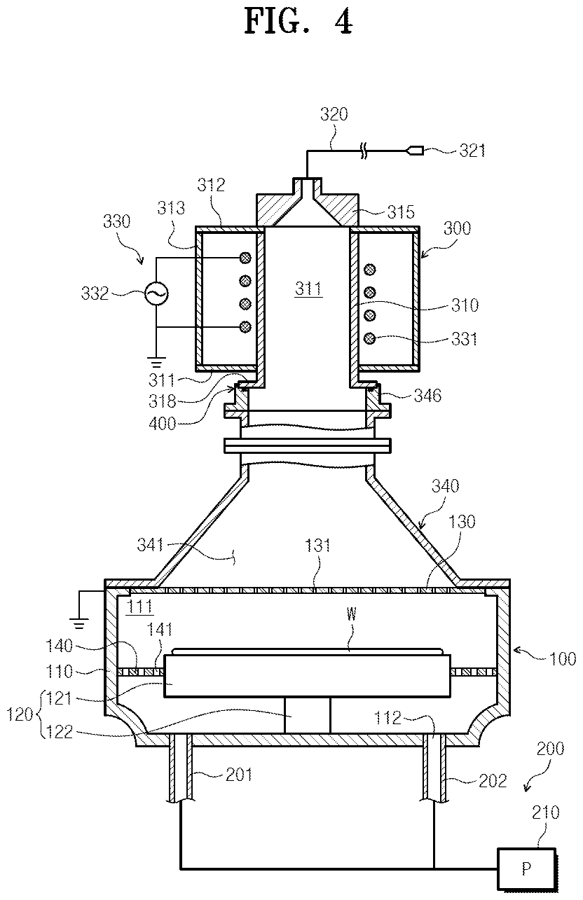

FIG. 4 is a diagram schematically illustrating an exemplary embodiment of a process chamber of the substrate processing apparatus of FIG. 3 that performs a plasma treatment process. Hereinafter, a process chamber 60 for performing a plasma treatment process according to the exemplary embodiment of the present invention will be described.

Referring to FIG. 4, the process chamber 60 performs a predetermined process on the substrate W by using plasma. In one example, a thin film on the substrate W may be etched or ashed. The thin film may be various types of films, such as a polysilicon film, an oxide film, or a silicon nitride film. Optionally, the film may be a natural oxide film or a chemically generated oxide film.

The process chamber 60 may include a process unit 100, an exhaust unit 200, and a plasma supplying unit 300.

The process unit 100 provides a space in which the substrate W is placed and in which processing on the substrate W is performed. A plasma is generated by discharging process gas in the plasma supplying unit 300 which is to be described later, and the generated plasma is supplied to the interior space of the process unit 100. Process gas that remains inside the process unit 100 and/or reaction by-products generated in the process of processing the substrate W are discharged to the outside of the process chamber 60 through the exhaust unit 200 described below. Thereby, the pressure within the process unit 100 may be maintained at a set pressure.

The process unit 100 may include a housing 110, a support unit 120, a baffle 130, and an exhaust baffle 140.

The interior of the housing 110 is provided with a processing space 111 where the substrate processing process is performed. An outer wall of the housing 110 may be provided with conductors. In one example, the outer wall of the housing 110 may be provided of a metal material including aluminum. The housing 110 may be open at the top, and an opening (not illustrated) may be formed in the side wall. The substrate W enters and exits the interior of the housing 110 through the opening. The opening (not illustrated) may be opened and closed by an opening member, such as a door (not illustrated). Additionally, an exhaust hole 112 may be formed in the bottom surface of the housing 110. The exhaust hole 112 may be connected with a configuration including the exhaust unit 200 which is to be described later.

The support unit 120 may be located in the processing space 111. The support unit 120 supports the substrate Win the processing space 111. On the top surface of the support unit 120, the substrate W requiring processing is placed. The support unit 120 may include a support plate 121 and a support shaft 122.

The support plate 121 may be provided in a substantially disk-like shape when viewed from the top. The support plate 121 is supported by the support shaft 122. The support plate 121 may be connected to an external power source (not illustrated). The support plate 121 may generate static electricity by power applied from an external power source. The electrostatic force of the generated static electricity may fix the substrate W to the top surface of the support plate 121. However, without limitation, the support plate 121 may support the substrate Win a physical manner, such as mechanical clamping, or in a vacuum adsorption manner.

The support shaft 122 may move the object. For example, the support shaft 122 may move the substrate W in an upward or downward direction. In one example, the support shaft 122 may engage the support plate 121 and raise and lower the support plate 121 to move the substrate W seated on the top surface of the support plate 121 up and down.

The baffle 130 is located above the support plate 121. The baffle 130 may be disposed between the support plate 121 and the plasma supplying unit 300. The baffle 130 may be provided of an aluminum material of which a surface is oxidized. The baffle 130 may be electrically connected to an upper wall of the housing 110. The baffle 130 may be provided in the shape of a disk having a substantial thickness. The baffle 130 may be provided in a substantially circular shape when viewed from the top. The baffle 130 may be disposed to overlap the top surface of the support unit 120 when viewed from above.

The baffle 130 is formed with baffle holes 131. The baffle holes 131 may be provided in a plurality. The baffle holes 131 may be spaced apart from each other. In one example, the baffle holes 131 may be formed at predetermined intervals on a concentric circumference for uniform radical supply. The baffle holes 131 may penetrate the baffle 130 from the top to the bottom. The baffle holes 131 may function as passageways for plasma generated by the plasma supply unit 300 to flow into the processing space 111.

The baffles 130 may uniformly deliver the plasma generated by the plasma supplying unit 300 to the processing space 111. In addition, the plasma diffused in a diffusion space 341 which is to be described later may pass through the baffle holes 131 and enter the processing space 111. In one example, charged particles, such as electrons or ions, may be trapped in the baffles 130, while uncharged neutral particles, such as oxygen radicals, may pass through the baffle holes 131 and be supplied to the substrate W. Additionally, the baffle 130 may be grounded to form a passageway through which electrons or ions move.

The baffle 130 of the exemplary embodiment of the present invention has been described above by way of example, but is not limited to, being provided in the form of a disk having a thickness. The baffle 130 according to the exemplary embodiment may have a circular shape when viewed from the top, but may also have a shape in which the height of the top surface increases from the edge region to the center region when viewed in cross-section. In one example, the baffle 130 may have a shape such that, when viewed in cross-section, its top surface slopes upwardly from an edge region to a center region. Accordingly, plasma generated from the plasma supplying unit 300 may flow along the inclined cross-section of the baffle 130 to the edge region of the processing space 111.

The exhaust baffle 140 uniformly exhausts plasma from the processing space 111 by zones. Additionally, the exhaust baffle 140 may adjust the residence time of the plasma flowing within the processing space 111. The exhaust baffle 140 has an annular ring shape when viewed from the top. The exhaust baffle 140 may be located between the inner wall of the housing 110 and the support unit 120 within the processing space 111. A plurality of exhaust holes 141 are formed in the exhaust baffle 140. The exhaust holes 141 may be provided as holes extending from a top to a bottom of the exhaust baffle 140. The exhaust holes 141 may be spaced apart from each other along a circumferential direction of the exhaust baffle 140. Reaction byproducts that have passed through the exhaust baffle 140 are discharged to the outside of the process unit 100 through the exhaust lines 201, 202 which are to be described below.

The exhaust unit 200 may exhaust process gases and/or impurities from the processing space 111 to the outside. The exhaust unit 200 may exhaust impurities and particles generated during the process of processing the substrate W to the outside of the process chamber 60. The exhaust unit 200 may include exhaust lines 201 and 202 and a pressure reducing member 210. The exhaust lines 201 and 202 function as passageways for plasma and/or reaction byproducts residing in the processing space 111 to be exhausted to the outside of the process chamber 60. The exhaust lines 201 and 202 may be connected to an exhaust hole 112 formed in the bottom surface of the housing 110. The exhaust lines 201 and 202 may be connected with the pressure reducing member 210 that provides negative pressure.

The pressure reducing member 210 may provide negative pressure to the processing space 111. The pressure reducing member 210 may discharge the plasma, impurities, or particles that remain in the processing space 111 to the outside of the housing 110. Additionally, the pressure reducing member 210 may provide negative pressure to maintain the pressure in the processing space 111 at a predetermined pressure. The pressure reducing member 123 may be a pump. However, the pressure reducing member 210 is not limited thereto, and may be provided with various variations of known devices that provide negative pressure.

The plasma supplying unit 300 may be located above the process unit 100. Further, the plasma supplying unit 300 may be located above the housing 110. In one example, the plasma supplying unit 300 may be separated from the process unit 100. In this case, the plasma supplying unit 300 may be provided on the exterior of the process unit 100. The plasma supplying unit 300 generates plasma from process gas supplied from a gas supply pipe 320, which will be described later, and supplies the generated plasma to the processing space 111.

The plasma supplying unit 300 may include a plasma chamber 310, a gas supply pipe 320, a plasma source 330, a diffusion member 340, and a sealing member 400.

Inside the plasma chamber 310, a discharge space 311 is formed. The plasma chamber 310 may have a shape with open top and bottom surfaces. In one example, the plasma chamber 310 may have a cylindrical shape with open top and bottom surfaces. The plasma chamber 310 may be made of a ceramic material.

The upper end of the plasma chamber 310 is sealed by a gas supply port 315. The gas supply port 315 is connected to the gas supply pipe 320. The process gas may be a reaction gas for plasma generation. In one example, the reaction gas may include difluoromethane (CH₂F₂), nitrogen (N₂), and oxygen (O₂). Optionally, the reaction gas may further include other types of gases, such as carbon tetrafluoromethane (CF₄), fluorine, hydrogen, and the like.

A lower flange 318 is formed at the lower end of the plasma chamber 310. The lower flange 318 may be connected to an upper flange 346 provided at the upper end of the diffusion member 340, which is described later.

Process gas is supplied to the discharge space 311 through the gas supply port 315. The process gas supplied to the discharge space 311 may be uniformly distributed to the processing space 111 through the diffusion space 341 and the baffle holes 131 which will be described later.

The plasma source 330 generates plasma by exciting process gas supplied to the discharge space 311. The plasma source 330 applies high frequency power to the discharge space 311 to excite the process gas supplied to the discharge space 311. The plasma source 330 may include an antenna 331 and a power source 332.

The antenna 331 may be an Inductively Coupled Plasma (ICP) antenna. The antenna 331 may be provided in a coiled shape. The antenna 331 may be external to the plasma chamber 310 and may wrap around the plasma chamber 310 multiple times. In one example, the antenna 331 may wrap multiple times around the plasma chamber 310 in a spiral shape on the outside of the plasma chamber 310.

The antenna 331 winds around the plasma chamber 310 in a region corresponding to the discharge space 311. One end of the antenna 331 may be provided at a height corresponding to an upper region of the plasma chamber 310, as viewed from right cross-section of the plasma chamber 310. The other end of the antenna 331 may be provided at a height corresponding to a lower region of the plasma chamber 310, as viewed from right cross-section of the plasma chamber 310. One end of the antenna 331 may be connected to the power source 332, and the other end of the antenna 331 may be grounded. However, without limitation, one end of the antenna 331 may be grounded and the other end of the antenna 331 may be connected to the power source 332.

The antenna 331 and the plasma chamber 310 may be provided as a single module surrounded by a first plate 311, a second plate 312, and a third plate 313. The first plate 311 may be provided on the lower end of the plasma chamber 310, and the second plate 312 may be provided on the upper end of the plasma chamber 310. The first plate 311 may be provided to span the lower of the plasma chamber 310. The first plate 311 and the plasma chamber 310 may be provided perpendicular to each other. The second plate 312 may be provided to span the upper end of the plasma chamber 310. The second plate 312 and the plasma chamber 310 may be provided perpendicular to each other. The third plate 313 may be provided to connect the first plate 311 and the second plate 312 to each other. The third plate 313 may form a side of the module.

The first plate 311, second plate 312, and third plate 313 may be provided of a metallic material. In one example, the first plate 311, the second plate 312, and the third plate 313 may be provided of aluminum.

The power source 332 may apply power to the antenna 331. The power source 332 may apply a high frequency current to the antenna 331. The high frequency current applied to the antenna 331 may form an induced electric field in the discharge space 311. The process gas supplied to the discharge space 311 may obtain energy for ionization from the induced electric field and be converted to a plasma state.

While the above described exemplary embodiments of the present invention are described by way of example in which the antenna 331 and the plasma chamber 310 are provided as a single module, the present invention is not limited thereto. In one example, the antenna 331 may not be modularized with the plasma chamber 310, but may be external to the plasma chamber 310, and may wind around the plasma chamber 310 multiple times.

The diffusion member 340 may diffuse the plasma generated by the plasma supplying unit 300 into the processing space 111. An interior of the diffusion member 340 is provided with a diffusion space 341 for diffusing plasma generated in the discharge space 311. The diffusion space 341 connects the processing space 111 and the discharge space 311, and functions as a passageway through which the plasma generated in the discharge space 311 is supplied to the processing space 111.

The diffusion member 340 may be formed substantially in the shape of an inverted funnel. The diffusion member 340 may have a shape that increases in diameter from the top to the bottom. The inner circumferential surface of the diffusion member 340 may be formed of a conductor. In one example, the inner circumferential surface of the diffusion member 340 may be provided of a material including quartz.

The diffusion member 340 is positioned between the housing 110 and the plasma chamber 310. The diffusion member 340 may be connected to the lower end of the plasma chamber 310. The upper end of the diffusion member 340 and the lower end of the plasma chamber 310 may be connected. The upper end of the diffusion member 340 is provided with the upper flange 346. The upper flange 346 is connected to the lower flange 318 of the plasma chamber 310. At the portion where the upper flange 346 and the lower flange 318 are connected to each other, the sealing member 400, described later, may be provided. The diffusion member 340 may seal the open upper surface of the housing 110. At the lower end of the diffusion member 340, the housing 110 and the baffle 130 may be engaged with each other.

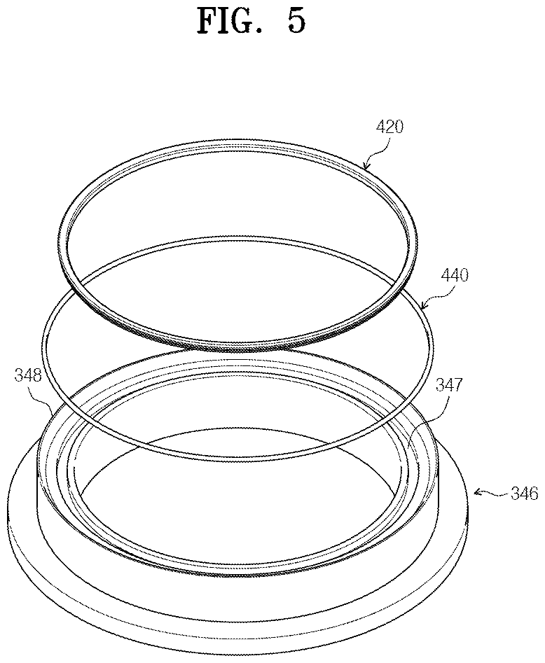

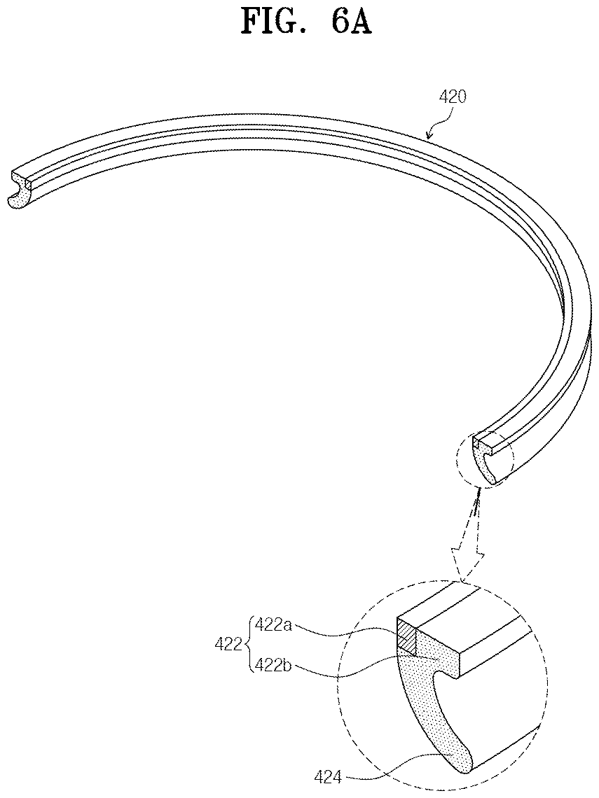

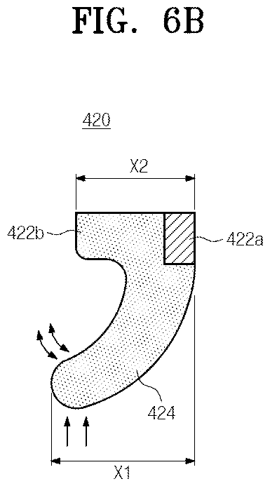

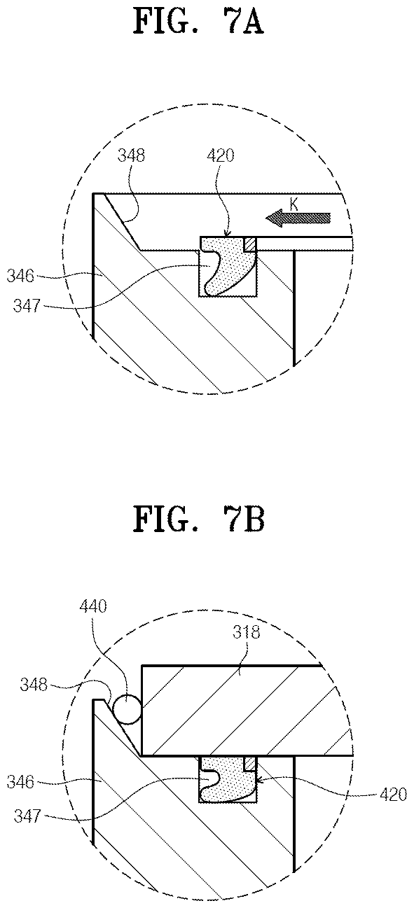

FIG. 5 is a perspective view schematically illustrating an exemplary embodiment of the sealing member and the upper flange of FIG. 4. FIG. 6A is a cutaway perspective view of an inner sealing member of FIG. 4. FIG. 6B is a cross-sectional view of the inner sealing member of FIG. 4. FIGS. 7A and 7B are drawings illustrating a sealing process by the sealing member of FIG. 4. Hereinafter, the upper flange and the sealing member according to the exemplary embodiment of the present invention will be described in detail with reference to FIGS. 5 to 7.

Referring to FIG. 5, the upper flange 346 is a part for connecting the diffusion member 340 and the plasma chamber 310 to each other. The upper flange 346 may be formed substantially in the shape of a ring. A mounting groove 347 is formed in the upper surface of the upper flange 346. The mounting groove 347 may be formed by being recessed downwardly from the upper surface of the upper flange 346. The mounting groove 347 may be formed along a peripheral direction of the upper surface of the upper flange 346. An inner sealing member 420 described later may be inserted into the mounting groove 347. The height of the mounting groove 347 may be less than the height of the inner sealing member 420 described later.

The upper edge of the upper flange 346 may have an inclined slope 348 formed to be inclined. The inclined surface 348 may be formed to surround a bottom edge of the lower flange 318. In one example, the inclined surface 348 may be formed with an upward inclination toward a direction away from the center of the diffusion space 341. In the intervening space formed by the combined edges of the inclined surface 348 and the upper flange 346, an outer sealing member 440 which is to be described later may be inserted.

The sealing member 400 may be provided where the lower flange 318 and the upper flange 346 are connected to each other. The sealing member 400 may minimize the inflow of external gases into the interior of the process chamber 60, or the escape of process gases from the interior of the process chamber 60, at the portion where the lower flange 318 and the upper flange 346 are connected to each other.

The sealing member 400 may include the inner sealing member 420 and the outer sealing member 440.

Referring to FIGS. 5 and 6, the inner sealing member 420 may be inserted into a mounting groove 347 formed in the upper flange 346. The inner sealing member 420 may be formed in a ring shape. The inner sealing member 420 may include a body portion 422 and a protrusion 424. For example, the body portion 422 and the protrusion 424 may be integrally formed. However, without limitation, the inner sealing members 420 may be separately machined or formed from different materials and joined in a non-adhesive manner.

The body portion 422 may be inserted into the mounting groove 347. The body portion 422 may be inserted into the mounting groove 347 such that the position thereof within the mounting groove 347 does not change. The upper surface of the body portion 422 may be provided flat. The upper surface of the body portion 422 may contact a lower surface of the lower flange 318 when the lower flange 318 and the upper flange 346 are in contact with each other. In the state where the lower surface of the protrusion 424 is supported on the bottom surface of the mounting groove 347, and in the state where the lower flange 318 is not in contact with the upper flange 346, the upper end of the body portion 422 may be positioned higher than the upper end of the mounting groove 347.

The body portion 422 may have a generally rectangular shape when viewed in cross-section. The body portion 422 may be formed with an inner portion 422a and an outer portion 422b.

The inner portion 422a is provided adjacent to the discharge space 311. The inner portion 422a is positioned relatively closer to the discharge space 311 than the outer portion 422b. For example, the inner portion 422a may be provided in an inner top region of the body portion 422. The inner portion 422a may be provided of a material that is highly corrosion resistant. The inner portion 422a is provided of a material that is more corrosion resistant to plasma than the outer portion 422b. The inner portion 422a according to the exemplary embodiment of the present invention may be formed of polytetrafluroethylene (PTFE). Optionally, the inner portion 422a may also be formed of Teflon.

The outer portion 422b is located relatively farther from the discharge space 311 than the inner portion 422a. For example, the outer portion 422b may be an area excluding the inner portion 422a. The outer portion 422b may be made of a different material from that of the inner portion 422a. In one example, the outer portion 422b may be provided of an elastically deformable material. The outer portion 422b may be deformed when the upper flange 346 and the lower flange 318 contact each other.

As illustrated in FIG. 7A, the protrusion 424 extends from the body portion 422. The protrusion 424 may extend in a downward direction from the lower end of the body portion 422. In one example, the protrusion 424 may be formed to be inclined in the down direction toward a direction away from the discharge space 311. As illustrated in FIG. 7A, the protrusion 424 may be formed to be inclined in the down direction toward a direction K in which hot plasma and/or process gas penetrates through the gap formed when the upper flange 346 and lower flange 318 are in contact with each other.

The protrusion 424 is provided of an elastically deformable material. The protrusion 424 may be deformed to seal the gap formed when the upper flange 346 and the lower flange 318 are in contact with each other. As illustrated in FIG. 7B, when the upper flange 346 and the lower flange 318 are in contact with each other, the protrusion 424 may be elastically deformed to seal the gap formed between the upper flange 346 and the lower flange 318. Additionally, when the upper flange 346 and the lower flange 318 are in contact with each other, the protrusion 424 is elastically deformed, thereby distributing the load of the lower flange 318 that is transferable to the inner sealing member 420. Thus, the durability of the inner sealing member 420 may be increased.

As illustrated in FIGS. 6B and 7, when viewed in cross-section, a width X1 of the protrusion 424 may be larger than a width X2 of the body portion 422. When viewed in cross-section, the width of the mounting groove 347 may be provided to be larger than the width X1 of the protrusion 424. By forming the width of the mounting groove 347 to be larger than the width of the inner sealing member 420, even though the internal pressure of the process chamber 60 repeatedly changes between vacuum and atmospheric pressure, the effect that the inner sealing member 420 may be subjected to due to differential pressure may be reduced.

The outer sealing member 440 may be inserted into the space formed by the combination of the edges of the inclined surface 348 and the upper flange 346. The outer sealing member 440 may be positioned a further outward side than the inner sealing member 420. In one example, the outer sealing member 440 may be located closer to the edge of the upper flange 346 than the inner sealing member 420. In other words, the outer sealing member 440 may be located a further outward side from the discharge space 311 than the inner sealing member 420. The outer sealing member 440 may be provided in a ring shape. In one example, the outer sealing member 440 may be provided in the form of an O-ring having a circular cross-section.

According to the exemplary embodiment of the above-described invention, by providing the inner portion 422a of a corrosion-resistant material, it is possible to minimize etching of the inner sealing member 420 from hot plasma and/or process gases that penetrate through the gap formed by the contact of the upper flange 346 and lower flange 318. Accordingly, the inner portion 422a may primarily prevent damage to the sealing member 400 from hot plasma and/or process gases.

Additionally, by providing the protrusions 424 of an elastically deformable material, the protrusion 424 may be elastically deformed to closely contact the lower surface of the mounting groove 347 when the upper flange 346 and lower flange 318 are in contact with each other. As a result, the gap that may be formed between the upper flange 346 and the lower flange 318 may be efficiently sealed. Accordingly, the protrusion 424 may secondarily prevent hot plasma and/or process gases from penetrating into the outer sealing member 440. Additionally, the internal pressure of the process chamber 60 may be efficiently maintained by the protrusion 424.

By preventing damage to the outer sealing member 440 by the inner sealing member 420, the life of the outer sealing member 440 may be improved. Accordingly, the cost or time required to maintain the sealing member 400 may be reduced. This results in the improvement of substrate (W) processing efficiency.

The outer sealing member 440 may ultimately form an atmosphere that seals the process chamber 60 from the outside environment to prevent hot plasma and/or process gases from escaping from the process chamber 60. This allows for pre-emptive blocking of particles and external gases that may enter the process chamber 60 from the outside, and final blocking of hot plasma and process gases that may escape from the process chamber 60.

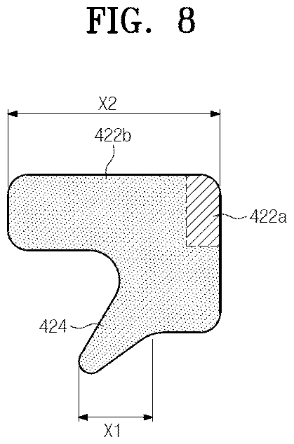

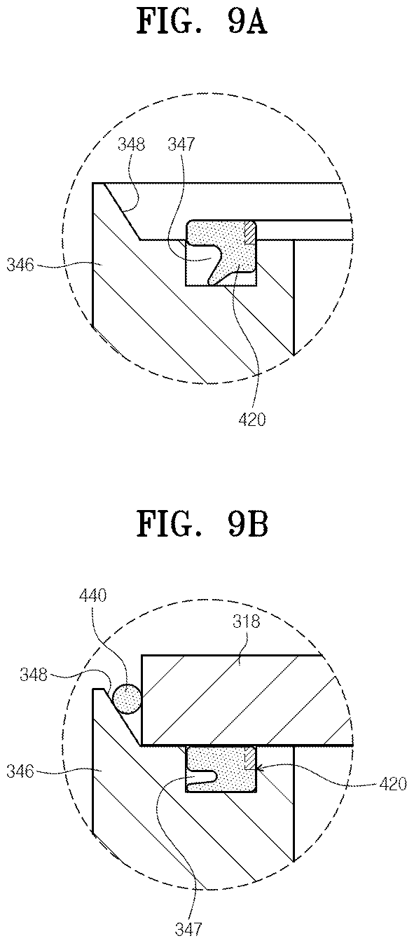

FIG. 8 is a diagram schematically illustrating another exemplary embodiment of the sealing member of FIG. 4. FIGS. 9A and 9B are drawings illustrating a sealing process by the sealing member of FIG. 8. The sealing member according to the exemplary embodiment of the present invention will be described in detail below with reference to FIGS. 8 and 9. The exemplary embodiment described below is provided similarly to the configurations for the substrate processing apparatus described above, with the exception of the inner sealing member. To avoid duplication of effort, we'll skip the description of duplicate configurations below.

Referring to FIG. 8, the inner sealing member 420 may be inserted into a mounting groove 347 formed in an upper flange 346. The inner sealing member 420 may be formed in a ring shape. The inner sealing member 420 may include a body portion 422 and a protrusion 424. For example, the body portion 422 and the protrusion 424 may be integrally formed. However, without limitation, the inner sealing members 420 may be separately machined or formed from different materials and joined in a non-adhesive manner. Hereinafter, the present invention will be described based on the case where the body portion 422 and the protrusion are integrally formed or processed as an example.

The body portion 422 may be inserted into the mounting groove 347. The body portion 422 may be inserted into the mounting groove 347 such that the position thereof within the mounting groove 347 does not change. In one example, an inner surface of the body portion 422 may be supported on an inner surface of the mounting groove 347. The upper surface of the body portion 422 may be provided flat. An upper surface of the body portion 422 may contact a lower surface of the lower flange 318 when the lower flange 318 and the upper flange 346 are in contact with each other, thereby supporting the inner sealing member 420.

The body portion 422 may have a generally quadrangular shape when viewed in cross-section. Optionally, the body portion 422 may be formed in the shape of a stepped rectangle when viewed in cross-section. In one example, the body portion 422 may be provided with a substantially “A” shape when viewed in cross-section. A stepped portion of the body portion 422 may have a protrusion 424, which is described later. As illustrated in FIG. 9A, in the state where the lower surface of the protrusion 424 supported on the bottom surface of the mounting groove 347, and in the state where the lower flange 318 is not in contact with the upper flange 346, the upper end of the body portion 422 may be positioned higher than the upper end of the mounting groove 347. The body portion 422 may be formed with an inner portion 422a and an outer portion 422b.

The inner portion 422a is provided adjacent to the discharge space 311. The inner portion 422a is positioned relatively closer to the discharge space 311 than the outer portion 422b. For example, the inner portion 422a may be provided in an inner top region of the body portion 422. The inner portion 422a may be provided of a material that is highly corrosion resistant. The inner portion 422a is provided of a material that is more corrosion resistant to plasma than the outer portion 422b. The inner portion 422a according to the exemplary embodiment of the present invention may be formed of polytetrafluroethylene (PTFE). Optionally, the inner portion 422a may also be formed of Teflon.

The outer portion 422b is located relatively farther from the discharge space 311 than the inner portion 422a. For example, the outer portion 422b may be an area excluding the inner portion 422a. The outer portion 422b may be made of a different material from that of the inner portion 422a. In one example, the outer portion 422b may be provided of an elastically deformable material. The outer portion 422b may be deformed when the upper flange 346 and the lower flange 318 contact each other.

The protrusion 424 may extend to protrude from the body portion 422. The protrusion 424 may extend from the lower end of the body portion 422. For example, the protrusion 424 may be formed to protrude downwardly from the stepped portion of the body portion 422. The protrusion 424 may be formed to be inclined. In one example, the protrusion 424 may be formed to be inclined in the down direction toward a direction away from the discharge space 311 of the body portion 422. As illustrated in FIGS. 8 and 9A, the protrusion 424 may be formed with a downward inclination toward the direction K in which hot plasma and/or process gases penetrate through the gap formed by the contact of the upper flange 346 and the lower flange 318 with each other.

The protrusion 424 is provided of an elastically deformable material. The protrusion 424 may be deformed to seal the gap formed when the upper flange 346 and the lower flange 318 are in contact with each other. As illustrated in FIG. 9A, the lower surface of the protrusion 424 may be supported on the bottom surface of the mounting groove 347. As illustrated in FIG. 9B, when the upper flange 346 and the lower flange 318 are in contact with each other, the protrusion 424 is elastically deformed to seal the gap formed between the upper flange 346 and the lower flange 318. Additionally, when the upper flange 346 and the lower flange 318 are in contact with each other, the protrusion 424 is elastically deformed, thereby distributing the load of the lower flange 318 that is transferable to the inner sealing member 420. Thus, the durability of the inner sealing member 420 may be increased.

As illustrated in FIG. 8, when viewed in cross-section, a width X2 of the body portion 422 may be provided to be greater than a width X1 of the protrusion 424. When viewed in cross-section, the width of the mounting groove 347 may be provided to be greater than the width X2 of the body portion 422. By forming the width of the mounting groove 347 to be larger than the width of the inner sealing member 420, even though the internal pressure of the process chamber 60 repeatedly changes between vacuum and atmospheric pressure, the effect that the inner sealing member 420 may be subjected to due to differential pressure may be reduced.

According to the exemplary embodiment of the above-described invention, by providing the inner portion 422a, which is exposed to plasma or the like relatively frequently, with a corrosion-resistant material, it is possible to minimize etching of the inner sealing member 420 from hot plasma and/or process gases that penetrate through the gap formed by the contact of the upper flange 346 and lower flange 318. Accordingly, the inner portion 422a may primarily prevent damage to the sealing member 400 from hot plasma and/or process gases.

Additionally, by providing the protrusions 424 of an elastically deformable material, the protrusion 424 may be elastically deformed to closely contact the bottom surface of the mounting groove 347 when the upper flange 346 and lower flange 318 are in contact with each other. The gap that may be formed between the upper flange 346 and the lower flange 318 may be efficiently sealed. Accordingly, the protrusion 424 may secondarily prevent hot plasma and/or process gases from penetrating into the outer sealing member 440. Additionally, the internal pressure of the process chamber 60 may be efficiently maintained by the protrusion 424.

By preventing damage to the outer sealing member 440 by the inner sealing member 420, the life of the outer sealing member 440 may be improved. Accordingly, the cost or time required to maintain the sealing member 400 may be reduced. This results in the improvement of substrate (W) processing efficiency.

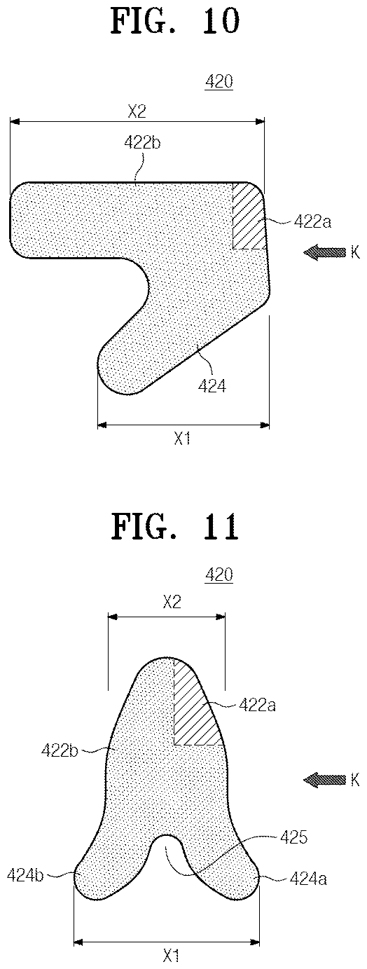

FIGS. 10 to 13 are drawings schematically illustrating other exemplary embodiments of the sealing member of FIG. 4.

Referring to FIG. 10, the inner sealing member 420 may be inserted into the mounting groove 347 formed in the upper flange 346. The inner sealing member 420 may be formed in a ring shape. The inner sealing member 420 may include a body portion 422 and a protrusion 424. For example, the body portion 422 and the protrusion 424 may be integrally formed. However, without limitation, the inner sealing members 420 may be separately machined or formed from different materials and joined in a non-adhesive manner.

The body portion 422 may be inserted into the mounting groove 347. The body portion 422 may be inserted into the mounting groove 347 such that the position thereof within the mounting groove 347 does not change. In one example, an inner surface of the body portion 422 may be supported on an inner surface of the mounting groove 347. The upper surface of the body portion 422 may be provided flat. An upper surface of the body portion 422 may contact a lower surface of the lower flange 318 when the lower flange 318 and the upper flange 346 are in contact with each other, thereby supporting the inner sealing member 420. The body portion 422 may have a generally quadrangular shape when viewed in cross-section.

In the state where the lower surface of the protrusion 424 is supported on the bottom surface of the mounting groove 347, and in the state where the lower flange 318 is not in contact with the upper flange 346, the upper end of the body portion 422 may be positioned higher than the upper end of the mounting groove 347. The body portion 422 may be formed with an inner portion 422a and an outer portion 422b.

The inner portion 422a is provided adjacent to the discharge space 311. The inner portion 422a is positioned relatively closer to the discharge space 311 than the outer portion 422b. For example, the inner portion 422a may be provided in an inner region of the body portion 422. The inner portion 422a may be provided of a material that is highly corrosion resistant. The inner portion 422a is provided of a material that is more corrosion resistant to plasma than the outer portion 422b. The inner portion 422a according to the exemplary embodiment of the present invention may be formed of polytetrafluroethylene (PTFE). Optionally, the inner portion 422a may also be formed of Teflon.

The inner portion 422a, which has a relatively high frequency of contact with hot plasma and/or process gases that penetrate through the gap formed by the contact of the upper flange 346 and the lower flange 318, is provided of a corrosion-resistant material. Therefore, it is possible to minimize etching of the inner sealing member 420 from hot plasma and/or process gases that penetrate through the gap formed by the contact of the upper flange 346 and lower flange 318. Accordingly, the inner portion 422a may prevent damage to the sealing member 400 from hot plasma and/or process gases.

The outer portion 422b is located relatively farther from the discharge space 311 than the inner portion 422a. For example, the outer portion 422b may be an area excluding the inner portion 422a. The outer portion 422b may be made of a different material from that of the inner portion 422a. In one example, the outer portion 422b may be provided of an elastically deformable material. The outer portion 422b may be deformed when the upper flange 346 and the lower flange 318 contact each other.

The protrusion 424 may extend to protrude from the body portion 422. The protrusion 424 may extend from the lower end of the body portion 422. For example, the protrusion 424 may be formed to protrude downwardly from the stepped portion of the body portion 422. The protrusion 424 may be formed to be inclined. In one example, the protrusion 424 may be formed to be inclined in the down direction toward a direction away from the discharge space 311 of the body portion 422. The protrusion 424 may be formed with a downward inclination toward the direction K in which hot plasma and/or process gases penetrate through the gap formed by the contact of the upper flange 346 and the lower flange 318 with each other.

The protrusion 424 is provided of an elastically deformable material. The protrusion 424 may be deformed to seal the gap formed when the upper flange 346 and the lower flange 318 are in contact with each other.

When the upper flange 346 and the lower flange 318 are in contact with each other, the protrusion 424 is elastically deformed to seal the gap formed between the upper flange 346 and the lower flange 318. Additionally, when the upper flange 346 and the lower flange 318 are in contact with each other, the protrusion 424 is elastically deformed, thereby distributing the load of the lower flange 318 that is transferable to the inner sealing member 420. Thus, the durability of the inner sealing member 420 may be increased.

When viewed in cross-section, a width X2 of the body portion 422 may be provided to be greater than a width X1 of the protrusion 424. When viewed in cross-section, the width of the mounting groove 347 may be provided to be greater than the width X2 of the body portion 422. By forming the width of the mounting groove 347 to be larger than the width of the inner sealing member 420, even though the internal pressure of the process chamber 60 repeatedly changes between vacuum and atmospheric pressure, the effect that the inner sealing member 420 may be subjected to due to differential pressure may be reduced.

Referring to FIG. 11, the inner sealing member 420 may be inserted into the mounting groove 347 formed in the upper flange 346. The inner sealing member 420 may be formed in a ring shape. The inner sealing member 420 may include a body portion 422 and a protrusion 424. For example, the body portion 422 and the protrusion 424 may be integrally formed. However, without limitation, the inner sealing members 420 may be separately machined or formed from different materials and joined in a non-adhesive manner.

The body portion 422 may be inserted into the mounting groove 347. In the state where the lower surface of the protrusion 424 is supported on the bottom surface of the mounting groove 347, and in the state where the lower flange 318 is not in contact with the upper flange 346, the upper end of the body portion 422 may be positioned higher than the upper end of the mounting groove 347. The upper surface of the body portion 422 contacts the lower surface of the lower flange 318 when the lower flange 318 and the upper flange 346 are in contact with each other, preventing hot plasma and/or process gases from entering from the gap formed by the contact of the lower flange 318 and the upper flange 346. The body portion 422 may be formed with an inner portion 422a and an outer portion 422b.

The inner portion 422a is provided adjacent to the discharge space 311. The inner portion 422a is positioned relatively closer to the discharge space 311 than the outer portion 422b. For example, the inner portion 422a may be provided in an inner region of the body portion 422. The inner portion 422a may be provided with a material that is highly corrosion resistant. The inner portion 422a is provided with a material that is more corrosion resistant to plasma than the outer portion 422b. The inner portion 422a according to the exemplary embodiment of the present invention may be formed of polytetrafluroethylene (PTFE). Optionally, the inner portion 422a may also be formed of Teflon.

The inner portion 422a, which has a relatively high frequency of contact with hot plasma and/or process gases that penetrate through the gap formed by the contact of the upper flange 346 and the lower flange 318, is provided of a corrosion-resistant material. Therefore, it is possible to minimize etching of the inner sealing member 420 from hot plasma and/or process gases that penetrate through the gap formed by the contact of the upper flange 346 and lower flange 318. Accordingly, the inner portion 422a may prevent damage to the sealing member 400 from hot plasma and/or process gases.

The outer portion 422b is located relatively farther from the discharge space 311 than the inner portion 422a. For example, the outer portion 422b may be an area excluding the inner portion 422a. The outer portion 422b may be made of a different material from that of the inner portion 422a. In one example, the outer portion 422b may be provided of an elastically deformable material. The outer portion 422b may be deformed when the upper flange 346 and the lower flange 318 contact each other.

The protrusion 424 may extend to protrude from the body portion 422. The protrusion 424 may extend in a downward direction from the lower end of the body portion 422. For example, the protrusion 424 may be shaped to diverge from the body portion 422 on either side, with a recess 425 provided therebetween. The protrusion 424 is provided of an elastically deformable material. The protrusion 424 may be deformed to seal the gap formed when the upper flange 346 and the lower flange 318 are in contact with each other. The protrusion 424 may include a first protrusion 424a and a second protrusion 424b.

The first protrusion 424a is located adjacent to the discharge space 311. For example, the first protrusion 424a may be formed at a location adjacent to the inner portion 422a. The first protrusion 424a is formed to have an inclination. The first protrusion 424a may be formed with an upward inclination toward a direction away from the inner portion 422a.

The second protrusion 424b is located adjacent to the discharge space 311. For example, the second protrusion 424b may be formed at a relatively distant location from the inner portion 422a compared to the first protrusion 424a. The second protrusion 424b is formed to have an inclination. The second protrusion 424b may be formed with a downward inclination toward a direction away from the inner portion 422a.

When the upper flange 346 and the lower flange 318 are in contact with each other, the protrusion 424 is elastically deformed to seal the gap formed between the upper flange 346 and the lower flange 318. Additionally, when the upper flange 346 and the lower flange 318 are in contact with each other, the protrusion 424 is elastically deformed, thereby distributing the load of the lower flange 318 that is transferable to the inner sealing member 420. Thus, the durability of the inner sealing member 420 may be increased.

Referring to FIG. 12, the description of the inner sealing member 420 according to the exemplary embodiment of the present invention is provided similarly to the inner sealing member 420 according to the exemplary embodiment described in FIG. 11, except for the shape of the body portion 422, so the shape of the body portion 422 will be described below.

The body portion 422 may be inserted into the mounting groove 347. In the state where the lower surface of the protrusion 424 is supported on the bottom surface of the mounting groove 347, and in the state where the lower flange 318 is not in contact with the upper flange 346, the upper end of the body portion 422 may be positioned higher than the upper end of the mounting groove 347. The upper surface of the body portion 422 contacts the lower surface of the lower flange 318 when the lower flange 318 and the upper flange 346 are in contact with each other, preventing hot plasma and/or process gases from entering from the gap formed by the contact of the lower flange 318 and the upper flange 346. The body portion 422 may have a generally quadrangular shape with both convex ends when viewed in cross-section.

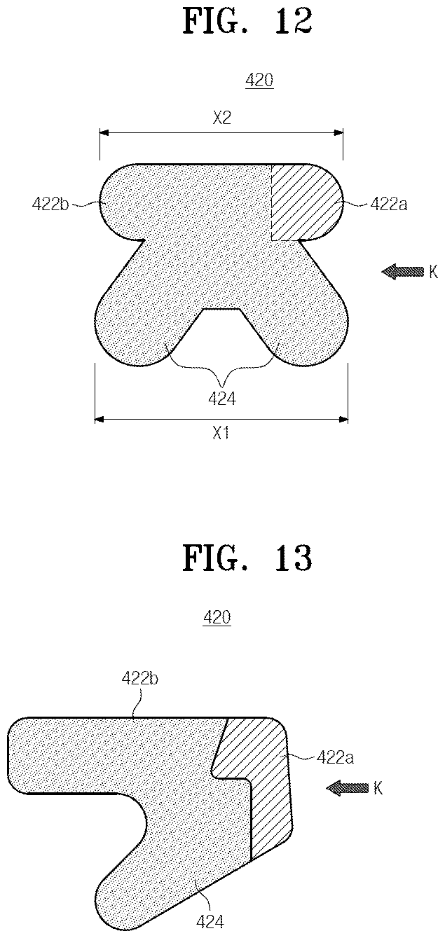

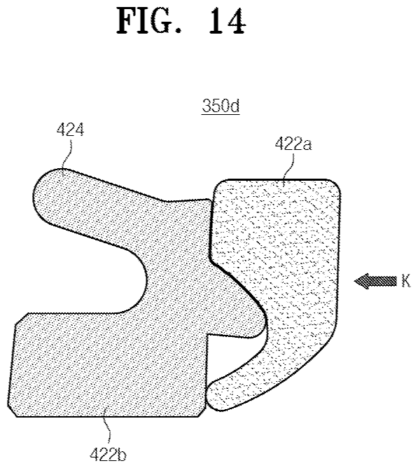

While some exemplary embodiments of the present invention have been described by using the example of the body portion 422 and the protrusion 424 being integrally formed, the present invention is not limited thereto. As illustrated in FIGS. 13 and 14, the inner sealing members 420 may be separately machined or formed from different materials and joined in a non-adhesive manner. In one example, the inner portion 422a, which is provided of a relatively corrosion-resistant material, may be machined separately from the outer portion 422b, which is provided of an elastically deformable material, and the protrusion 424 to be joined in a non-adhesive manner.

When the inner sealing member 420 is formed in a non-adhesive manner, thermal expansion may occur in the inner sealing member 420 due to hot plasma or process gas. Due to thermal expansion of the inner portion 422a and thermal expansion of the outer portion 422b and protrusions 424, stresses may be generated between each of the processed members. Therefore, it is possible to minimize the phenomenon of separation between the respective processed members during the processing of the substrate W.

The above described exemplary embodiments of the present invention are illustrated by way of example, but are not limited to, the case where the inner portion 422a and the outer portion 422b are formed of different materials. For example, both inner portion 422a and outer portion 422b may be provided of an elastically deformable material. Optionally, the entire body portion 422 may be provided with a material that is highly corrosion resistant to hot plasma and/or process gases.

The foregoing detailed description illustrates the present invention. Furthermore, the foregoing is described in terms of exemplary embodiments of the invention, and the invention may be used in a variety of other combinations, modifications, and environments. This means that changes or modifications may be made to the scope of the concepts of the invention disclosed herein, to the extent that they are equivalent to the original invention, and/or to the extent of the skill or knowledge in the art. The disclosed exemplary embodiments describe the best state of the art for implementing the technical spirits of the invention, and various changes are possible as required by specific applications and uses of the invention. Accordingly, the foregoing detailed description of the invention is not intended to limit the invention to the disclosed exemplary embodiments. The appended claims should also be construed to include other exemplary embodiments.

1. An apparatus for processing a substrate, the apparatus comprising:
a housing providing a processing space therein;
a support unit disposed within the housing and supporting a substrate; and
a plasma generating unit provided above the housing,
wherein the plasma supplying unit includes:
a plasma chamber with a discharge space formed inside;
a diffusion member provided between the plasma chamber and the housing, and diffusing plasma;
a plasma source for generating plasma in the discharge space from process gas; and
a sealing member provided between a lower flange of the plasma chamber and an upper flange of the diffusion member, and
the sealing member includes:
an inner sealing member inserted into a mounting groove formed in an upper surface of the upper flange; and
an outer sealing member inserted into a space formed by combination of the upper flange and the lower flange, and positioned at a further outward side from the discharge space than the inner sealing member.

2. The apparatus of claim 1, wherein the inner sealing member includes:
a body portion inserted into the mounting groove; and
a protrusion formed to protrude from the body portion, and
the body portion includes an inner portion provided at an inner side from the discharge space and an outer portion provided at an outer side from the discharge space.

3. The apparatus of claim 2, wherein the inner portion is provided of a material that is more corrosion resistant to plasma than a material of the outer portion.

4. The apparatus of claim 2, wherein the outer portion and/or the protrusion is formed of a elastically deformable material to seal a gap formed by a contact of the upper flange and the lower flange.

5. The apparatus of claim 2, wherein the protrusion extends from a lower end of the body portion, and is formed with an inclination.

6. The apparatus of claim 5, wherein the protrusion is formed with a downward inclination toward a direction away from the discharge space.

7. The apparatus of claim 2, wherein the protrusion extends from an upper end of the body portion and is formed with an upward inclination in a direction away from the discharge space.

8. The apparatus of claim 2, wherein a width of the protrusion is provided to be smaller than a width of the body portion when viewed in cross-section.

9. The apparatus of claim 2, wherein a width of the protrusion is provided to be greater than a width of the body portion when viewed in cross-section.

10. The apparatus of claim 1, wherein the upper flange has an inclined surface at an edge to surround an edge of the lower flange, and
the space is formed by combination of the inclined surface and the edge of the lower flange.

11. The apparatus of claim 1, wherein the sealing member is provided in a ring shape.

12. An apparatus for processing a substrate, the apparatus comprising:
a sealing member for sealing a gap between a first member and a second member, which is in contact with the first member,
wherein the sealing member includes:
an inner sealing member inserted into a mounting groove formed in an upper surface of the second member; and
an outer sealing member provided on a further outer side than the inner sealing member, and inserted into a space formed at edges of the first member and the second member, and
the inner sealing member includes:
a body portion inserted into a mounting groove formed in an upper surface of the first member; and
a protrusion formed to protrude from the body portion.

13. The apparatus of claim 12, wherein the body portion is formed by an inner portion provided at an inner side of the body portion and an outer portion provided at an outer side of the body portion.

14. The apparatus of claim 13, wherein the inner portion is provided of a material that is more corrosion resistant to plasma than a material of the outer portion.

15. The apparatus of claim 13, wherein the outer portion and/or the protrusion is formed of an elastically deformable material.

16. The apparatus of claim 13, wherein the protrusion extends from a lower end of the body portion and formed with an inclination.

17. The apparatus of claim 16, wherein the protrusion is formed with a downward inclination toward a direction away from the inner portion.

18. The apparatus of claim 13, wherein the protrusion includes:
a first protrusion formed with an upward inclination toward a direction away from the inner portion; and
a second protrusion formed with a downward inclination toward a direction away from the inner portion.

19. The apparatus of claim 13, wherein the protrusion extends from an upper end of the body portion and is formed with an upward inclination toward a direction away from the inner portion.

20. The apparatus of claim 12, wherein the sealing member is provided in a ring shape.
